(19) United States
(12) Patent Application Publication
(10) Pub. No.: US 2014/0016273 A1
(43) Pub. Date: Jan. 16, 2014

(54) ELECTRONIC COMPONENT WITH HEAT-DISSIPATING PLATE AND BOARD EMPLOYING SAID COMPONENT

(71) Applicant: Nathalie Combet, Cugnaux (FR)

(72) Inventor: Nathalie Combet, Cugnaux (FR)

(21) Appl. No.: 14/003,488

(22) PCT Filed: Mar. 30, 2012
(86) PCT No.: PCT/EP12/01407

§ 371 Date: Oct. 1, 2013

(30) Foreign Application Priority Data
Apr. 8, 2011 (FR) 11/01074

(51) Int. Cl. H05K 7/20

(52) U.S. Cl. CPC H05K 7/2039
USPC 361/720; 361/704

(57) ABSTRACT

Electronic component includes a plurality of pins (10) to be soldered onto a printed circuit (2), the component furthermore including a heat-dissipating plate (11) for dissipating heat originating from the component (1), the heat-dissipating plate (11) being intended to be soldered onto a conducting region (211) on the surface of the printed circuit (2), the component further including testing elements (110, 10a) in the form of a pin (10a) directly electrically connected to the heat-dissipating plate (11) for monitoring electrical characteristics of the connection established between the heat-dissipating plate (11) and the conducting region (211), such as the continuity or the impedance. An electronic board incorporating the component is also described.

The invention relates to an electronic component with a heat-dissipating plate designed to be soldered onto a printed circuit, together with a board using this component.

Whether they are designed as a power switch or for performing logic processing, electronic components consume electrical power which is then transformed into heat in the component. In order to ensure the correct operation of the component, it is necessary to dissipate this heat.

Amongst the techniques available for addressing this issue, one is known which consists in providing a metal heat-dissipating plate on the surface of the component and in soldering this heat-dissipating plate onto a conducting region of a printed circuit. A thermal bridge is thus established between the component and the printed circuit which allows the heat to be widely diffused and allows it to be dissipated by radiation and by convection. In order to further improve the diffusion of the heat, interconnection holes may be provided passing through the conducting region. The reason for this is that the interconnection holes comprise a surface coating, in general made of copper, which is thermally conducting and which helps to transfer the heat onto the face of the printed circuit opposite to that on which the component is soldered.

The conducting region is a part of a metal layer, in general made of copper, which is deposited onto the surface of the printed circuit. It allows the solder to be received by brazing the heat-dissipating plate. The soldering technique is for example that of surface mounted components.

In order for the heat-dissipating plate to perform its function well, it is necessary for the solder joint to be well formed on the conducting region. A poor solder joint would result in an abnormal rise in temperature of the component and a poor mechanical retention. The visual or mechanical inspection of the solder joint is however difficult to achieve since the heat-dissipating plate is hidden under the component.

The invention aims to provide means for verifying the correct mounting of an electronic component comprising a heat-dissipating plate.

With these objectives in mind, the subject of the invention is an electronic component comprising a plurality of pins to be soldered onto a printed circuit, the component furthermore comprising a heat-dissipating plate for dissipating the heat originating from the component, the heat-dissipating plate being intended to be soldered onto a conducting region on the surface of the printed circuit, the component being characterized in that it comprises testing means for testing electrical characteristics of the connection established between the heat-dissipating plate and the conducting region.

By verifying the electrical characteristics of the connection between the heat-dissipating plate and the heat dissipation region, it is possible to determine whether the solder joint also provides a mechanical and thermal connection between them. The electrical measurements can be simple to perform.

According to a first embodiment, the testing means comprise a pin directly electrically connected to the heat-dissipating plate. The pin is accessible from outside of the component. A testing instrument can thus be connected between the pin and the conducting region in order to carry out a test or a measurement.

According to a second embodiment, the testing means comprise a circuit connected to the heat-dissipating plate and to a reference voltage source for testing electrical characteristics between the heat-dissipating plate and the reference voltage source when the conducting region is connected to the reference voltage source. By placing the testing means inside the component, using a dedicated pin is obviated, in contrast to the first embodiment. A connection is established that includes the heat-dissipating plate, the conducting region, and the reference voltage source, and the characteristics of this assembly are monitored with the circuit. The latter can form part of a more complete assembly that tests the whole of the component.

The testing means monitor for example an electrical characteristic chosen from between the electrical continuity and the impedance. The electrical continuity is simple to test and allows assemblies where the component might not be soldered to be detected. The measurement of the impedance enables a more rigorous verification that allows the assemblies where the solder joint may only be partial to be taken into account. The measurement is made for example at various frequencies, and for each frequency, the measurement is compared with a predetermined threshold beyond which the solder joint is deemed to be bad.

According to one particular embodiment, the testing means are integrated into a shift register of a boundary scanning chain. Such means are frequently used for testing the component during its manufacture or its mounting, and are known by the term ‘boundary scan’. By integrating the testing means into the register, few specific means are dedicated to performing this test.

Another subject of the invention is an electronic board comprising a printed circuit, characterized in that it furthermore comprising a component such as previously defined, the printed circuit comprising a conducting region onto which the heat-dissipating plate of the component is soldered.

According to one improvement, the printed circuit comprises interconnection holes in the conducting region. These interconnection holes participate in the dissipation of heat. They also allow the conducting region to be electrically connected to the reference voltage source via another conducting layer.

The invention will be better understood and other features and advantages will become apparent upon reading the description that follows, the description making reference to the appended drawings amongst which:

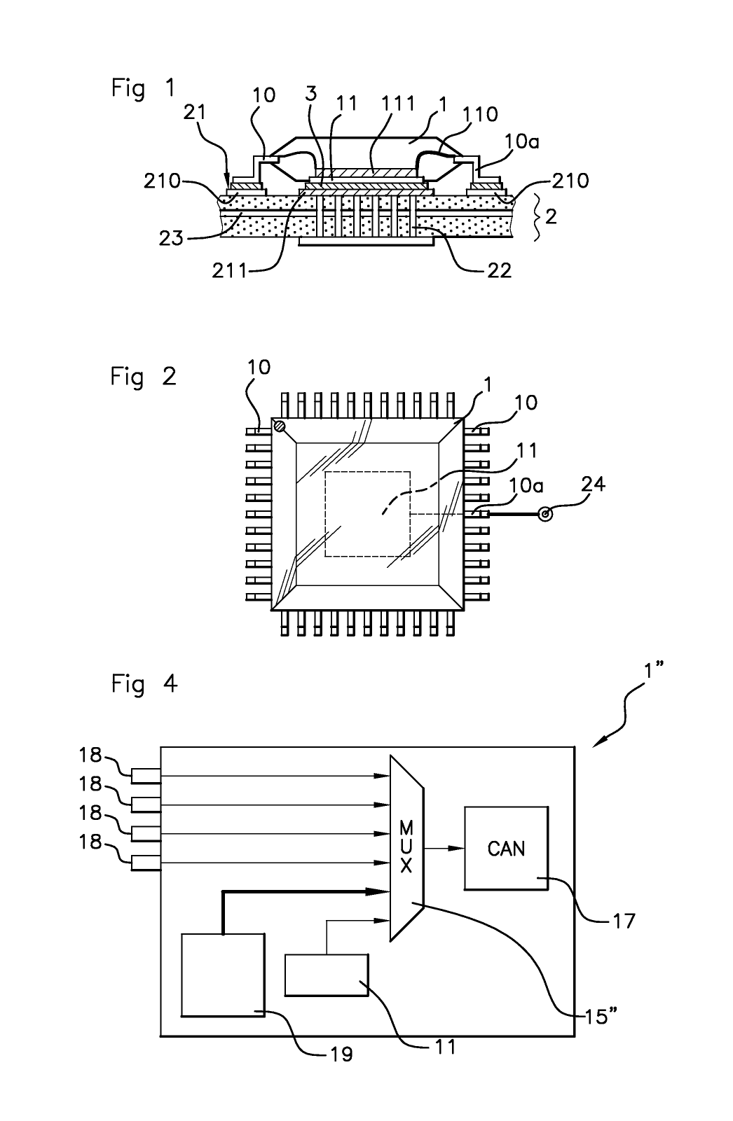

FIG. 1 is a cross-sectional view of a board according to a first embodiment of the invention;

FIG. 2 is a top view of the component in FIG. 1 mounted onto a printed circuit;

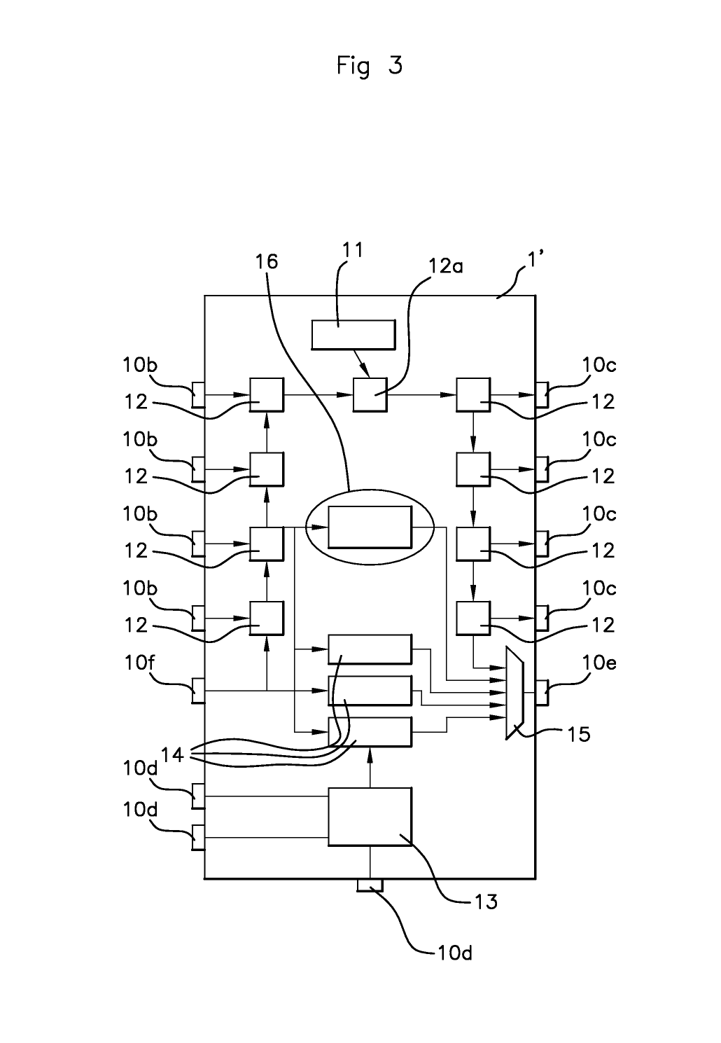

FIG. 3 is a schematic view of a component according to the invention according to a second embodiment;

FIG. 4 is a schematic view of a component according to the invention according to a third embodiment.

According to a first embodiment of the invention, an electronic component 1, such as is shown in FIG. 2, comprises a casing of substantially plane shape and from which bonding tabs (or pins) 10 protrude all around its periphery. On a lower face, the component 1 comprises a heat-dissipating plate 11 onto which is fixed an electronic chip 111.

The component 1 is fixed to the surface of a printed circuit 2, here a printed circuit with three conducting layers. For this purpose, the upper layer 21 of the printed circuit 2, which is a conducting layer, is dissected so as to leave tracks 210 remaining each of which receives pins 10, and a conducting region 211 having the dimensions of the heat-dissipating plate 11.

The printed circuit 2 furthermore comprises interconnection holes 22 passing through the circuit in the conducting region 211. Conventionally, the interconnection holes 22 are metalized on their inner surface and they provide an electrical link between the conducting region 211 and the intermediate conducting layer 23. They also provide a thermal conduction from one face to the other of the printed circuit 2. The heat-dissipating plate 11 is soldered onto this conducting region 211 by brazing 3.

According to the invention, the conducting region 211 is connected to a dedicated pin 10a of the electronic component 1 via an electrical link 110, as shown in FIG. 1. This pin 10a is connected to a pin 24 on the electronic board in order to be able to connect a test instrument to it. Thus, by connecting the test instrument between the pin 24 and one of the interconnection holes 22 of the conducting region 211, the electrical conductivity between the conducting region 211 and the heat-dissipating plate 11 may be verified. The test instrument can also measure the impedance of the circuit thus formed and determine whether this value falls outside of a predetermined range of values.

According to a second embodiment of the invention (cf. FIG. 3), the component 1′ comprises a boundary scanning chain. The component 1′ thus comprises pins 10b dedicated to inputs, pins 10c dedicated to outputs and pins 10d dedicated to control inputs. The component 1′ also comprises a test input 10f and a test output 10e. Each input pin 10b and output pin 10c is connected to a cell 12 of the scanning chain, the cells 12 being connected together in such a manner as to form a shift register. The component 1′ furthermore conventionally comprises a controller 13 connected to the control inputs 10d, and several registers 14 connected, on the one hand, to the test input 10f, and on the other, to the test output 10e by means of a multiplexer 15. The component 1′ also comprises a logic circuit 16 connected to the cells 12 of the scanning chain and to the input and to the multiplexer 15 of the test output.

According to the invention, the scanning chain comprises a heat-dissipating plate cell 12a whose input is connected to the heat-dissipating plate 11. Thus, during the test procedures, the logic state of the heat-dissipating plate 11 is able to be known, and hence it can be deduced from this whether the latter is connected or not to the conducting region 211. Such a solution requires very little adaptation of a component in order to perform the test of the connection of the heat-dissipating plate 11, by limiting it to the addition of a cell 12a in the scanning chain.

In a third embodiment of the invention, shown schematically in FIG. 4, the component 1″ comprises an analog/digital converter 17 for carrying out measurements of voltage on analog inputs 18 and on internal probes 19. The analog inputs 18 and the probes 19 are connected to the converter 17 by means of a multiplexer 15″. According to the invention, the heat-dissipating plate 11 is connected to one of the inputs of the multiplexer 15″. Thus, by selecting a measurement on the heat-dissipating plate 11, its voltage can be known as a function of the reference voltage which may be applied to the conducting region 211. From this, an impedance is then deduced and hence a diagnostic on the quality of the contact between the conducting region 211 and the heat-dissipating plate 11.

1. An electronic component comprising a plurality of pins (10) to be soldered onto a printed circuit (2), the component furthermore comprising a heat-dissipating plate (11) for dissipating heat originating from the component (1), the heat-dissipating plate (11) being intended to be soldered onto a conducting region (211) on the surface of the printed circuit (2), the component (1) being characterized in that it comprises testing means (110, 10a) in the form of a pin (10a) directly electrically connected to the heat-dissipating plate (11) for testing electrical characteristics of the connection established between the heat-dissipating plate (11) and the conducting region (211).

2. The component as claimed in claim 1, in which the testing means comprise a circuit (17) connected to the heat-dissipating plate (11) and to a reference voltage source for monitoring electrical characteristics between the heat-dissipating plate (11) and the reference voltage source when the conducting region (211) is connected to the reference voltage source.

3. The component as claimed in claim 2, in which the testing means monitor an electrical characteristic chosen from between the electrical continuity and the impedance.

4. The component as claimed in claim 2, in which the testing means are integrated into a shift register (12, 12a) of a boundary scanning chain.

5. An electronic board comprising a printed circuit (2), characterized in that it furthermore comprises a component (1) as claimed in claim 1, the printed circuit (2) comprising a conducting region (211) onto which the heat-dissipating plate (11) of the component (1) is soldered.

6. The board as claimed in claim 5, in which the printed circuit (2) comprises interconnection holes (22) within the conducting region (211).

7. An electronic board comprising a printed circuit (2), characterized in that it furthermore comprises a component (1) as claimed in claim 2, the printed circuit (2) comprising a conducting region (211) onto which the heat-dissipating plate (11) of the component (1) is soldered.

8. An electronic board comprising a printed circuit (2), characterized in that it furthermore comprises a component (1) as claimed in claim 3, the printed circuit (2) comprising a conducting region (211) onto which the heat-dissipating plate (11) of the component (1) is soldered.

9. An electronic board comprising a printed circuit (2), characterized in that it furthermore comprises a component (1) as claimed in claim 4, the printed circuit (2) comprising a conducting region (211) onto which the heat-dissipating plate (11) of the component (1) is soldered.
